(19) United States
(12) Patent Application Publication
(10) Pub. No.: US 2016/0322251 A1
(43) Pub. Date: Nov. 3, 2016

(54) FILM FOR SEMICONDUCTOR DEVICE, METHOD FOR MANUFACTURING SEMICONDUCTOR DEVICE, AND SEMICONDUCTOR DEVICE

(71) Applicant: NITTO DENKO CORPORATION, Osaka (JP)

(72) Inventors: Naohide TAKAMOTO, Osaka (JP); Ryuichi KIMURA, Osaka (JP)

(73) Assignee: NITTO DENKO CORPORATION, Osaka (JP)

(21) Appl. No.: 15/139,901

(22) Filed: Apr. 27, 2016

(30) Foreign Application Priority Data
Apr. 30, 2015 (JP) 2015-092992

(51) Int. Cl. H01L 21/683; B32B 43/00; H01L 21/78

(52) U.S. Cl. CPC H01L 21/6836; H01L 21/78; B32B 43/006; H01L 2221/68327; H01L 2221/68386

(57) ABSTRACT

The film for a semiconductor device has a plurality of films with attached dicing tape for the backside of a flip-chip type semiconductor arranged on a separator at a prescribed interval and an outer sheet arranged outside the film with attached dicing tape for the backside of a flip-chip type semiconductor; the film with attached dicing tape for the backside of a flip-chip type semiconductor has a dicing tape and a film for the backside of a flip-chip type semiconductor; and when the length of the narrowest portion of the outer sheet is set to G and the length from the long side of the separator to the dicing tape is set to F, G is within the range from 0.2 times to 0.95 times F.

### BACKGROUND OF THE INVENTION

1. Field of the Invention

The present invention relates to a film for a semiconductor device, a method for manufacturing a semiconductor device, and a semiconductor device.

2. Description of the Related Art

In recent years, thinner and smaller semiconductor device and its package have been desired even more. Therefore, as a semiconductor device and its package, a flip-chip type semiconductor device has been broadly used in which a semiconductor element such as a semiconductor chip is mounted on a substrate by flip-chip bonding. The flip-chip bonding is a method of fixing and electrically connecting the semiconductor chip to the substrate so that the circuit surface of the semiconductor chip is facing to the electrode formation surface of the substrate. In the semiconductor device described above, etc., the backside of the semiconductor chip may be protected with a film for the backside of a flip-chip type semiconductor to prevent damage, etc. of the semiconductor chip (for example, refer to Patent Document 1).

As disclosed in Patent Document 1, the film for the backside of a flip-chip type semiconductor described above may be provided as a film with attached dicing tape for the backside of a flip-chip type semiconductor in which a dicing tape is pasted to the film.

The film with attached dicing tape for the backside of a flip-chip type semiconductor can be used as follows. First, a semiconductor wafer is pasted onto a film for the backside of a flip-chip type semiconductor of the film with attached dicing tape for the backside of a flip-chip type semiconductor. Next, the semiconductor wafer and the film for the backside of a flip-chip type semiconductor are diced while being held by the dicing tape. Then, semiconductor chips together with the film for the backside of a flip-chip type semiconductor are peeled from the dicing tape, and individually collected.

The above-described film with attached dicing tape for the backside of a flip-chip type semiconductor may be provided as a film for a semiconductor device in which films with attached dicing tape for the backside of a flip-chip type semiconductor were cut in advance each into a shape matching the shape of the semiconductor wafer to which the film is pasted (for example, a circular shape) or the shape of a ring frame (for example, a circular shape) and the films are laminated on a long separator at a prescribed interval in a state capable of being peeled in view of the workability in pasting the film to the semiconductor wafer and mounting the film to the ring frame in dicing.

The above-described film for a semiconductor device may be wound in a roll shape for transportation or storage.

### PRIOR ART DOCUMENT

### Patent Document

Patent Document 1: JP-A-2010-199541

### SUMMARY OF THE INVENTION

However, the thickness of the portion where the film with attached dicing tape for the backside of a flip-chip type semiconductor of the film for a semiconductor device is laminated (the total thickness of the separator and the film with attached dicing tape for the backside of a flip-chip type semiconductor) becomes larger than that of the portion where the film with attached dicing tape for the backside of a flip-chip type semiconductor is not laminated (the thickness of the separator alone). Accordingly, if the film for a semiconductor device is wound in a roll shape, a film for the backside of a flip-chip type semiconductor may be pressed against the edges of other films for the backside of a flip-chip type semiconductor, and a winding trace may be transferred.

The film for the backside of a flip-chip type semiconductor is normally marked by using various methods such as a printing method and a laser marking method. Accordingly, if a winding trace is transferred to the film for the backside of a flip-chip type semiconductor, there is a problem that the visibility of various pieces of information to be marked deteriorates.

The present invention has been made in consideration of the above-described problem, and an object thereof is to provide a film for a semiconductor device that suppresses transfer of a trace to a film for the backside of a flip-chip type semiconductor when the film for a semiconductor device is wound in a roll shape in which films with attached dicing tape for the backside of a flip-chip type semiconductor are laminated on a separator at a prescribed interval and suppresses deterioration of the visibility of various pieces of information to be marked, a method for manufacturing a semiconductor device using the film for a semiconductor device, and a semiconductor device manufactured with the method for manufacturing a semiconductor device.

The present inventors have found that the above-described problem can be solved by adopting the following configuration and completed the present invention.

That is, the film for a semiconductor device according to the present invention is characterized to have a long separator, a plurality of films with attached dicing tape for the backside of a flip-chip type semiconductor arranged on the separator in a row at a prescribed interval, and an outer sheet arranged outside the film with attached dicing tape for the backside of a flip-chip type semiconductor and laminated on the separator so as to include long sides of the separator; in which the film with attached dicing tape for the backside of a flip-chip type semiconductor has a dicing tape and a film for the backside of a flip-chip type semiconductor laminated on the dicing tape not to protrude from the dicing tape, and the film with attached dicing tape for the backside of a flip-chip type semiconductor are laminated on the separator so that the separator and the film for the backside of a flip-chip type semiconductor serve as a pasting surface; and when the length of the narrowest portion of the outer sheet is set to G and the length from the long side of the separator to the dicing tape is set to F, G is within the range from 0.2 times to 0.95 times F.

According to the above-described configuration, the outer sheet exists outside the films with attached dicing tape for the backside of a flip-chip type semiconductor. That is, the outer sheet exists on a portion of the separator where the films with attached dicing tape for the backside of a flip-chip type semiconductor are not laminated. Therefore, the difference in thickness becomes small between the portion where the films with attached dicing tape for the backside of a flip-chip type semiconductor exist and the portion where they do not exist. Therefore, the transfer of a winding trace can be reduced caused by the difference in level between the portion where the films with attached dicing tape for the backside of a flip-chip type semiconductor exist and the portion where they do not exist.

In addition, G is within the range from 0.2 times to 0.95 times F. In other words, the gap between the outer sheet and the film with attached dicing tape for the backside of a flip-chip type semiconductor is within a fixed range. Because G is 0.2 times F or more and the gap is relatively narrow, the transfer of the winding trace can be reduced. On the other hand, because G is 0.95 times F or less, the generation of wrinkles can be suppressed when the film is wound in a roll shape. Further, the film with attached dicing tape for the backside of a flip-chip type semiconductor can be easily peeled from the separator without being caught by the outer sheet.

In the above-described configuration, G is preferably 2 mm or more.

If G is 2 mm or more, the gap between the outer sheet and the film with attached dicing tape for the backside of a flip-chip type semiconductor can be made narrower. Therefore, the transfer of the winding trace can be reduced further.

In the above-described configuration, when the length from the long side of the separator to the film for the backside of a flip-chip type semiconductor is set to E, E is preferably within the range from 1 times to 5 times F.

If E is within the range from 1 times to 5 times F, the film for the backside of a flip-chip type semiconductor has a certain size in planar view although the size is the same as or smaller than that of the dicing tape. Therefore, transfer of the winding trace to a backside protection film can be reduced.

In the above-described configuration, the thickness of the film for the backside of a flip-chip type semiconductor is preferably 5 μm to 100 μm.

If the thickness of the film for the backside of a flip-chip type semiconductor is 5 μm or more, the backside of a wafer can be protected, and thus its strength is increased. On the other hand, if the thickness of the film for the backside of a flip-chip type semiconductor is 100 μm or less, peeling of the film from the separator can be suppressed.

In the above-described configuration, the film for a semiconductor device is preferably wound in a roll shape.

Because the film for the backside of a flip-chip type semiconductor is less subject to the transfer of the winding trace even if the film is wound in a roll shape, the film for a semiconductor device is easily transported or stored if the film is wound in a roll shape.

The method for manufacturing a semiconductor device according to the present invention is characterized to have a step of peeling the film with attached dicing tape for the backside of a flip-chip type semiconductor from the film for a semiconductor device, a step of pasting a semiconductor wafer onto the film for the backside of a flip-chip type semiconductor of the peeled film with attached dicing tape for the backside of a flip-chip type semiconductor, a step of performing laser marking on the film for the backside of a flip-chip type semiconductor, a step of dicing the semiconductor wafer to form a semiconductor element, a step of peeling the semiconductor element together with the film for the backside of a flip-chip type semiconductor from a pressure-sensitive adhesive layer, and a step of flip-chip bonding the semiconductor element to an adherend.

According to the above-described configuration, because the film for a semiconductor device is used, the transfer of the winding trace to the film for the backside of a flip-chip type semiconductor is suppressed. Therefore, the visibility of laser marking performed on the film for the backside of a flip-chip type semiconductor becomes satisfactory.

The semiconductor device according to the present invention is characterized to be manufactured with the method for manufacturing a semiconductor device.

According to the above-described configuration, because the semiconductor device is manufactured using the film for a semiconductor device, the transfer of the winding trace to the film for the backside of a flip-chip type semiconductor is suppressed. Therefore, the visibility of laser marking performed on the film for the backside of a flip-chip type semiconductor becomes satisfactory.

### BRIEF DESCRIPTION OF THE DRAWINGS

FIG. 1 is a schematic plan view of the film for a semiconductor device according to one embodiment of the present invention;

FIG. 2 is an X-X cross section of the film for a semiconductor device shown in FIG. 1; and

FIGS. 3(a) to 3(e) are schematic cross sections showing one example of the method for manufacturing a semiconductor device using the film for a semiconductor device according to one embodiment of the present invention.

### DETAILED DESCRIPTION OF THE PREFERRED EMBODIMENTS

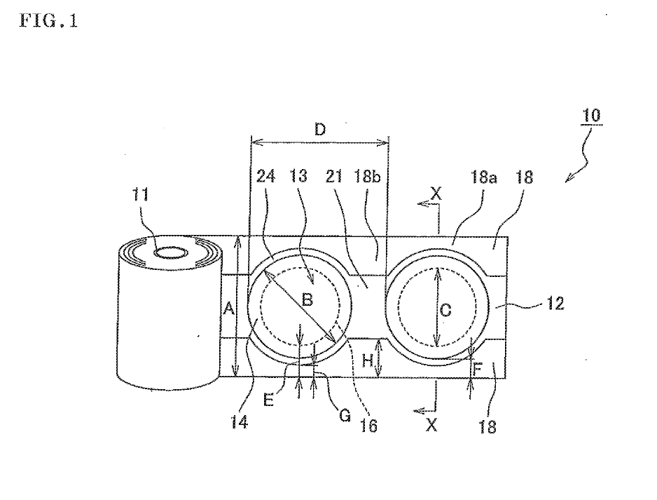

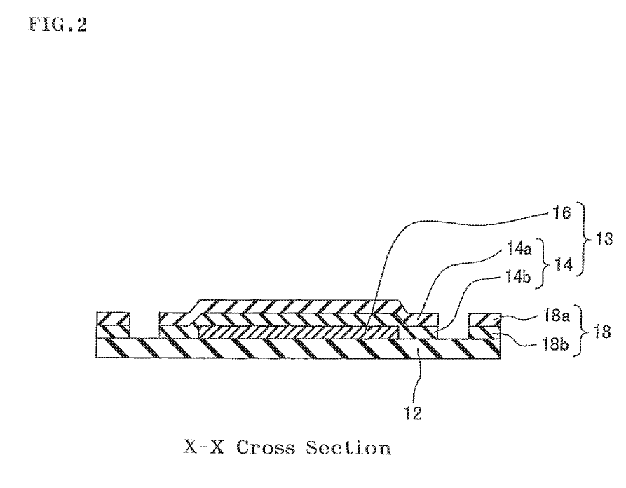

The film for a semiconductor device according to the present embodiment will be explained below by referring to the drawings. FIG. 1 is a schematic plan view of the film for a semiconductor device according to one embodiment of the present invention, and FIG. 2 is an X-X cross section of the film for a semiconductor device shown in FIG. 1.

### (Film for Semiconductor Device)

As shown in FIG. 1, a film 10 for a semiconductor device according to the present embodiment is wound around a cylindrical winding core 11 into a roll shape. The film for a semiconductor device according to the present invention may not be wound into a roll shape. However, the film for a semiconductor device is preferably wound into a roll shape from a viewpoint of easy transportation and storage. As described later, because transfer of a winding trace of the film 10 for a semiconductor device to a film 16 for the backside of a flip-chip type semiconductor is suppressed, deterioration of the visibility of various pieces of information to be marked is suppressed even if the film is wound in a roll shape.

For example, the winding start edge of the film 10 for a semiconductor device to be wound is adhered to the winding core 11 and the winding core 11 is rotated in the winding direction to wind the film 10 for a semiconductor device.

First, the positional relationship of layers constituting the film 10 for a semiconductor device and their shapes will be explained below.

The film 10 for a semiconductor device has a long separator 12, a plurality of films 13 with attached dicing tape for the backside of a flip-chip type semiconductor, and an outer sheet 18. In the present embodiment, the film 13 with attached dicing tape for the backside of a flip-chip type semiconductor has a circular shape. However, the shape of the film with attached dicing tape for the backside of a flip-chip type semiconductor of the present invention is not limited to a circular shape.

A width A of the separator 12 differs depending on the size of the film 13 with attached dicing tape for the backside of a flip-chip type semiconductor, and the width is 290 mm to 390 mm for example.

The separator 12 (the long side of the separator 12) preferably has a length in which two or more of the films 13 with attached dicing tape for the backside of a flip-chip type semiconductor can be arranged at a prescribed interval, and the separator 12 has normally a length in which 10 to 500 of the films 13 can be arranged. The specific length is about 3 m to 200 m for example.

The films 13 with attached dicing tape for the backside of a flip-chip type semiconductor are arranged on the separator 12 in a row in the length direction of the separator 12 at a prescribed interval. Specifically, a distance D between one of the films 13 with attached dicing tape for the backside of a flip-chip type semiconductor and an adjacent film 13 with attached dicing tape for the backside of a flip-chip type semiconductor is 270 mm to 390 mm for example.

The films 13 with attached dicing tape for the backside of a flip-chip type semiconductor are arranged closer to [near, toward] the center in the width direction of the separator 12 so that the films 13 do not cover the long sides of the separator 12. In the present embodiment, the films 13 with attached dicing tape for the backside of a flip-chip type semiconductor are arranged so that the centers of all the films 13 are positioned on the center in the width direction of the separator 12.

The film 13 with attached dicing tape for the backside of a flip-chip type semiconductor has a dicing tape 14 and a film 16 for the backside of a flip-chip type semiconductor laminated on the dicing tape 14.

The film 16 for the backside of a flip-chip type semiconductor is laminated on the dicing tape 14 so as not to protrude from the dicing tape 14 in planar view. In the present embodiment, the center of the dicing tape 14 matches the center of the film 16 for the backside of a flip-chip type semiconductor in planar view.

The film 13 with attached dicing tape for the backside of a flip-chip type semiconductor is laminated on the separator 12 so that the separator 12 and the film 16 for the backside of a flip-chip type semiconductor serve as a pasting surface.

The thickness of the film 16 for the backside of a flip-chip type semiconductor is preferably 5 μm to 100 μm, more preferably 7 μm 80 μm, and further preferably 10 μm to 50 μm regardless of the size of each layer constituting the film 10 for a semiconductor device. If the thickness of the film 16 for the backside of a flip-chip type semiconductor is 5 μm or more, the backside of a wafer can be protected, and thus its strength is increased. On the other hand, if the thickness of the film 16 for the backside of a flip-chip type semiconductor is 100 μm or less, peeling of the film from the separator can be suppressed.

A diameter B of the dicing tape 14 is 260 mm to 380 mm for example. A diameter C of the film 16 for the backside of a flip-chip type semiconductor is 199 mm to 350 mm for example.

The outer sheet 18 is arranged outside the films 13 with attached dicing tape for the backside of a flip-chip type semiconductor (outside the width direction of the separator 12). Further, the outer sheet 18 is arranged on the separator 12 so as to cover the long sides of the separator 12.

According to the film 10 for a semiconductor device, the outer sheet 18 exists on a portion of the separator 12 where the films 13 with attached dicing tape for the backside of a flip-chip type semiconductor are not laminated. Therefore, the difference in thickness becomes small between the portion where the films 13 with attached dicing tape for the backside of a flip-chip type semiconductor exist and the portion where they do not exist. Therefore, the transfer of a winding trace can be reduced caused by the difference in level between the portion where the films 13 with attached dicing tape for the backside of a flip-chip type semiconductor exist and the portion where they do not exist.

In the present embodiment, the width of an outer portion 18a in the portion of the outer sheet 18 where the films 13 with attached dicing tape for the backside of a flip-chip type semiconductor are arranged (corresponding to the length G of the portion of the outer sheet 18 having the narrowest width). The width of an outer portion 18b in a portion 21 between one of the films 13 with attached dicing tape for the backside of a flip-chip type semiconductor and an adjacent film 13 with attached dicing tape for the backside of a flip-chip type semiconductor (corresponding to the length H in FIG. 1) is wider than that of the portion 18a.

In the film 10 for a semiconductor device, when the length of the narrowest portion (18a in the present embodiment) of the outer sheet 18 is set to G and the length from the long side of the separator 12 to the dicing tape 14 is set to F, G is within the range from 0.2 times to 0.95 times F, and preferably from 0.3 times to 0.9 times F. G is within the range from 0.2 times to 0.95 times F. In other words, the width of a gap 24 between the outer sheet 18 and the film 13 with attached dicing tape for the backside of a flip-chip type semiconductor is within a fixed range. Because G is 0.2 times F or more and the gap 24 is relatively narrow, the transfer of the winding trace can be reduced. On the other hand, because G is 0.95 times F or less, the generation of wrinkles can be suppressed when the film is wound in a roll shape. Further, the film 13 with attached dicing tape for the backside of a flip-chip type semiconductor can be easily peeled from the separator 12 without being caught by the outer sheet 18.

Regardless of the size of each layer constituting the film 10 for a semiconductor device, G is preferably 2 mm or more. If G is 2 mm or more, the gap between the outer sheet 18 and the film 13 with attached dicing tape for the backside of a flip-chip type semiconductor can be made narrower. Therefore, the transfer of the winding trace can be further reduced.

When the length from the long side of the separator 12 to the film 16 for the backside of a flip-chip type semiconductor is set to E, E is preferably within the range from 1 times to 5 times F, and more preferably from 2 times to 4 times F.

If E is within the range from 1 times to 5 times F, the film 16 for the backside of a flip-chip type semiconductor has a certain size in planar view although the size is the same as or smaller than that of the dicing tape 14. Therefore, transfer of the winding trace to a backside protection film can be reduced.

An example of more specific size combinations of A to H is as follows.

A: 290 mm to 390 mm

B: 270 mm to 370 mm

C: 200 mm to 340 mm

D: 280 mm to 380 mm

E: 10 mm to 40 mm

F: 5 mm to 40 mm

G: 2 mm to 30 mm

H: 0 mm to 180 mm

The dicing tape 14 has a base 14a and a pressure-sensitive adhesive layer 14b formed on the base 14a. The dicing tape 14 and the film 16 for the backside of a flip-chip type semiconductor are pasted to each other so that the pressure-sensitive adhesive layer 14b serves as a pasting surface. When the dicing tape 14 and the film 16 for the backside of a flip-chip type semiconductor are pasted to each other, the separator 12 is pasted to the portion where the film 16 for the backside of a flip-chip type semiconductor does not exist if such portion exists.

The outer sheet 18 has a base 18a and a pressure-sensitive adhesive layer 18b formed on the base 18a. In the present embodiment, the base 18a is preferably made of the same material and preferably has the same thickness as the base 14a. The pressure-sensitive adhesive layer 18b is preferably made of the same material and preferably has the same thickness as the pressure-sensitive adhesive layer 14b. The constituting materials of the outer sheet 18 are not particularly limited as long as the outer sheet 18 can be pasted to the separator 12. However, the thickness of the outer sheet 18 is preferably about 0.5 times to 5 times that of the dicing tape 14 from a viewpoint of suppressing the winding trace. From a viewpoint of suppressing the winding trace, the thickness of the outer sheet 18 is preferably about 0.8 times to 2 times that of the film 13 with attached dicing tape for the backside of a flip-chip type semiconductor.

The positional relationship of layers constituting the film 10 for a semiconductor device and their shapes were explained above.

Next, the constituting materials of layers constituting the film 10 for a semiconductor device will be explained below.

(Film for the Backside of a Flip-Chip Semiconductor)

The film 16 for the backside of a flip-chip type semiconductor (the film 16 for the backside of a semiconductor) preferably formed by containing a thermosetting resin and a thermoplastic resin.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET (polyethylene terephthalate) and PBT (polybutylene terephthalate), a polyamideimide resin, and a fluororesin. The thermoplastic resins can be used alone or two types or more can be used together. Of these thermoplastic resins, acrylic resin is particularly preferable since the resin contains ionic impurities in only a small amount and has a high heat resistance so as to make it possible to ensure the reliability of the semiconductor element.

The acrylic resin is not especially limited, and examples thereof include a polymer having one type or two types or more of acrylates or methacrylates having a linear or branched alkyl group having 30 or less carbon atoms (preferably 4 to 18 carbon atoms, further preferably 6 to 10 carbon atoms, and especially preferably 8 or 9 carbon atoms) as a component. That is, the acrylic resin of the present invention has a broad meaning and also includes a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers that can form the above-described acrylic resin (monomers other than an alkylester of acrylic acid or methacrylic acid having an alkyl group having 30 or less carbon atoms) are not especially limited. Examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate. Among these, a carboxyl group-containing monomer is preferable from the viewpoint that the tensile storage modulus Ea of the die bond film can be set at a preferred value. (Meth)acrylate refers to an acrylate and/or a methacrylate, and every “(meth)” in the present invention has the same meaning.

Among these, an acrylic resin is preferable that is formed from a material containing acrylonitrile, acryloyl morpholine, etc. as monomer components from a viewpoint of improving the heat resistance of the film 40 for the backside of a semiconductor.

Examples of the thermosetting resin include an epoxy resin, a phenol resin, an amino resin, an unsaturated polyester resin, a polyurethane resin, a silicone resin, and a thermosetting polyimide resin. The thermosetting resins can be used alone or two types or more can be used together. An epoxy resin having a small amount of ionic impurities that erode the semiconductor element is especially suitable as the thermosetting resin. Further, a phenol resin can be suitably used as a curing agent for the epoxy resin.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Among the above-described epoxy resins, a novolak type epoxy resin, a biphenyl type epoxy resin, a trishydroxyphenylmethane type epoxy resin, and a tetraphenylolethane type epoxy resin are especially preferable. These epoxy resins are highly reactive with a phenol resin as a curing agent and are excellent in heat resistance.

The phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, a resol type phenol resin, and polyoxystyrenes such as polyparaoxystyrene. The phenol resins can be used alone or two types or more can be used together. Among these phenol resins, a phenol novolak resin and a phenol aralkyl resin are especially preferable because connection reliability of the c can be improved.

The phenol resin is suitably compounded in the epoxy resin so that a hydroxyl group in the phenol resin to 1 equivalent of an epoxy group in the epoxy resin component becomes 0.5 to 2.0 equivalents. The ratio is more preferably 0.8 to 1.2 equivalents. When the compounding ratio goes out of this range, sufficient curing reaction does not proceed, and the characteristics of the epoxy resin cured substance easily deteriorate.

A thermal curing accelerating catalyst for an epoxy resin and a phenol resin may be used in the present invention. The thermal curing accelerating catalyst is not especially limited, and the catalyst can be appropriately selected from known thermal curing accelerating catalysts. The thermal curing accelerating catalysts can be used alone or two types or more can be used together. Examples of the thermal curing accelerating catalyst include an amine curing accelerator, a phosphorus curing accelerator, an imidazole curing accelerator, a boron curing accelerator and a phosphorus-boron curing accelerator.

The film 16 for the backside of a semiconductor are suitably formed of a resin composition containing an epoxy resin and a phenol resin and a resin composition containing an epoxy resin, a phenol resin, and an acrylic resin. Because these resins have few ionic impurities and high heat resistance, reliability of the semiconductor element can be ensured.

It is important that the film 16 for the backside of a semiconductor has tackiness (adhesion) to the backside (the surface where a circuit is not formed) of a semiconductor wafer. The film 16 for the backside of a semiconductor can be formed of a resin composition containing an epoxy resin as a thermosetting resin, for example. A polyfunctional compound that reacts with a functional group of the end of the polymer molecular chain is preferably added as a crosslinking agent to crosslink the film 16 for the backside of a semiconductor to some extent in advance. With this operation, the adhesion characteristics under high temperature can be improved and the heat resistance can be improved.

The crosslinking agent is not especially limited, and a known crosslinking agent can be used. Specific examples thereof include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. An isocyanate crosslinking agent and an epoxy crosslinking agent are preferable. The crosslinking agents can be used alone or two type or more can be used together.

Examples of the isocyanate crosslinking agent include lower aliphatic polyisocyanates such as 1,2-ethylene diisocyanate, 1,4-butylene isocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethane diisocyanate, and xylylene diisiocyanate. A trimethylolpropane/tolylene diisocyanate trimer adduct (tradename: Coronate L manufactured by Nippon Polyurethane Industry Co., Ltd.) and a trimethylolpropane/hexamethylene diisocyanate trimer adduct (tradename: Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerythritol polyglycidylether, polyglyserol polyglycidylether, sorbitan polyglycidylether, trimethylolpropane polyglycidylether, diglycidyl adipate, diglycidyl o-phthalate, triglycidyl-tris(2-hydroxyethyl)isocyanurate, resorcin diglycidylether, bisphenol-s-diglycidyl ether, and an epoxy resin having two or more epoxy groups in the molecule.

The used amount of the crosslinking agent is not especially limited, and can be appropriately selected according to the level of crosslinking. Specifically, the used amount of the crosslinking agent is normally preferably 7 parts by weight or less (0.05 to 7 parts by weight, for example) to 100 parts by weight of a polymer component (especially, a polymer having a functional group at the end of the molecular chain) for example. When the used amount of the crosslinking agent is more than 7 parts by weight to 100 parts by weight of the polymer component, it is not preferable because the adhering strength decreases. From the viewpoint of improving cohesive strength, the used amount of the crosslinking agent is preferably 0.05 parts by weight or more to 100 parts by weight of the polymer component.

In the present invention, it is possible to perform a crosslinking treatment by irradiation with an electron beam, an ultraviolet ray, or the like in place of using the crosslinking agent or together with a crosslinking agent.

The film 40 for the backside of a semiconductor normally includes coloring agent. With this configuration, the films 16 for the backside of a semiconductor is colored and can exhibit an excellent marking property and an excellent appearance, and a semiconductor device can be obtained having an appearance with added value. Because the colored film for the backside of a semiconductor has an excellent marking property, various information such as character information and pattern information can be given to a semiconductor device or the surface where a circuit is not formed of the semiconductor device in which the semiconductor element is marked through the film for the backside of a semiconductor using various marking methods such as a printing method and a laser marking method. Especially, the information such as character information and pattern information that is given by marking can be recognized visually with excellent visibility by controlling the color. Because the film for the backside of a semiconductor is colored, the dicing tape and the film for the backside of a semiconductor can be easily distinguished, and workability can be improved. It is possible to color-code the semiconductor device by product, for example. When the film for the backside of a semiconductor is colored (when it is not colorless or transparent), the color is not especially limited. However, the color is preferably a dark color such as black, blue, or red, and black is especially preferable.

In this embodiment, the dark color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

In this embodiment, L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

A coloring agent corresponding to the desired color may be used in the film 40 for the backside of a semiconductor. Various dark color materials such as black color materials, blue color materials, and red color materials can be preferably used, and black color materials are especially preferable. The coloring agents include any of pigments, dyes, etc. The coloring agent may be used either alone or in combination of two or more types. Further, the dyes can be used in any form of acid dyes, reactive dyes, direct dyes, disperse dyes, cationic dyes, etc. Further, the form of the pigments is not especially limited, and it can be appropriately selected from the known pigments and used.

When dyes are used as the coloring agents, the films 16 for the backside of a semiconductor (consequently the film 10 with attached dicing tape for the backside of a flip-chip type semiconductor) having uniform or almost uniform coloring concentration can be easily manufactured because the dyes disperse uniformly or almost uniformly due to dissolution in the films 16 for the backside of a semiconductor. Because of that, when the dyes are used as the coloring agents, the coloring concentration of the film for the backside of a semiconductor in the film with attached dicing tape for the backside of a flip-chip type semiconductor can be made uniform or almost uniform, and the marking property and the appearance can be improved.

The black color material is not especially limited, and can be appropriately selected from inorganic black pigments and black dyes, for example. The black color material may be a color material mixture in which a cyan color material (blue-green color material), a magenta color material (red-purple color material), and a yellow color material are mixed together. The black color materials can be used alone or two types or more can be used together. The black color materials can be used also with other color materials other than black.

Specific examples of the black color materials include carbon black such as furnace black, channel black, acetylene black, thermal black, and lamp black, graphite (black lead), copper oxide, manganese dioxide, azo pigments such as azomethine azo black, aniline black, perylene black, titanium black, cyanine black, activated carbon, ferrite such as nonmagnetic ferrite and magnetic ferrite, magnetite, chromium oxide, iron oxide, molybdenum disulfide, chromium complex, complex oxide black, and anthraquinone organic black.

In the present invention, black dyes such as C. I. solvent black 3, 7, 22, 27, 29, 34, 43, and 70, C. I. direct black 17, 19, 22, 32, 38, 51, and 71, C. I. acid black 1, 2, 24, 26, 31, 48, 52, 107, 109, 110, 119, and 154, and C. I. disperse black 1, 3, 10, and 24; and black pigments such as C. I. pigment black 1 and 7 can be used as the black color material.

Examples of the black coloring materials commercially available include trade name “Oil Black BY”, trade name “Oil Black BS”, trade name “Oil Black HBB”, trade name “Oil Black 803”, trade name “Oil Black 860”, trade name “Oil Black 5970”, trade name “Oil Black 5906”, and trade name “Oil Black 5905” (manufactured by Orient Chemical Industries Co., Ltd.)

Examples of color materials other than the black color materials include a cyan color material, a magenta color material, and a yellow color material. Examples of the cyan color material include cyan dyes such as C. I. solvent blue 25, 36, 60, 70, 93, and 95; and C. I. acid blue 6 and 45; and cyan pigments such as C. I. pigment blue 1, 2, 3, 15, 15:1, 15:2, 15:3, 15:4, 15:5, 15:6, 16, 17, 17:1, 18, 22, 25, 56, 60, 63, 65, and 66; C. I. vat blue 4 and 60; and C. I. pigment green 7.

Examples of the magenta color material include magenta dyes such as C. I. solvent red 1, 3, 8, 23, 24, 25, 27, 30, 49, 52, 58, 63, 81, 82, 83, 84, 100, 109, 111, 121, and 122; C. I. disperse red 9; C. I. solvent violet 8, 13, 14, 21, and 27; C. I. disperse violet 1; C. I. basic red 1, 2, 9, 12, 13, 14, 15, 17, 18, 22, 23, 24, 27, 29, 32, 34, 35, 36, 37, 38, 39, and 40; and C. I. basic violet 1, 3, 7, 10, 14, 15, 21, 25, 26, 27, and 28.

Examples of the magenta color material include magenta pigments such as C. I. pigment red 1, 2, 3, 4, 5, 6, 7, 8, 9, 10, 11, 12, 13, 14, 15, 16, 17, 18, 19, 21, 22, 23, 30, 31, 32, 37, 38, 39, 40, 41, 42, 48:1, 48:2, 48:3, 48:4, 49, 49:1, 50, 51, 52, 52:2, 53:1, 54, 55, 56, 57:1, 58, 60, 60:1, 63, 63:1, 63:2, 64, 64:1, 67, 68, 81, 83, 87, 88, 89, 90, 92, 101, 104, 105, 106, 108, 112, 114, 122, 123, 139, 144, 146, 147, 149, 150, 151, 163, 166, 168, 170, 171, 172, 175, 176, 177, 178, 179, 184, 185, 187, 190, 193, 202, 206, 207, 209, 219, 222, 224, 238, and 245; C. I. pigment violet 3, 9, 19, 23, 31, 32, 33, 36, 38, 43, and 50; and C. I. vat red 1, 2, 10, 13, 15, 23, 29, and 35.

Examples of the yellow color material include yellow dyes such as C. I. solvent yellow 19, 44, 77, 79, 81, 82, 93, 98, 103, 104, 112, and 162; and yellow pigments such as C. I. pigment orange 31 and 43, C. I. pigment yellow 1, 2, 3, 4, 5, 6, 7, 10, 11, 12, 13, 14, 15, 16, 17, 23, 24, 34, 35, 37, 42, 53, 55, 65, 73, 74, 75, 81, 83, 93, 94, 95, 97, 98, 100, 101, 104, 108, 109, 110, 113, 114, 116, 117, 120, 128, 129, 133, 138, 139, 147, 150, 151, 153, 154, 155, 156, 167, 172, 173, 180, 185, and 195, and C. I. vat yellow 1, 3, and 20.

Various color materials such as cyan color materials, magenta color materials, and yellow color materials can be used alone or two types or more can be used together. When two types or more of various color materials such as cyan color materials, magenta color materials, and yellow color materials are used, the mixing ratio or the compounding ratio of these color materials is not especially limited, and can be appropriately selected according to the types of each color material and the intended color.

Other additives can be appropriately compounded in the film 16 for the backside of a semiconductor as necessary. Examples of the other additives include a filler, a flame retardant, a silane coupling agent, an ion trapping agent, an extender, an anti-aging agent, an antioxidant, and a surfactant.

The filler may be any of an inorganic filler and an organic filler. However, an inorganic filler is preferable. By adding a filler such as an inorganic filler, electric conductivity can be given to the film 16 for the backside of a semiconductor, heat conductivity can be improved, and the elastic modulus can be adjusted. The film 16 for the backside of a semiconductor may be electrically conductive or non-conductive. Examples of the inorganic filler include ceramics such as silica, clay, gypsum, calcium carbonate, barium sulfate, alumina oxide, beryllium oxide, silicon carbide, and silicon nitride, metals such as aluminum, copper, silver, gold, nickel, chromium, lead, tin, zinc, palladium, and solder, alloys, and various inorganic powders consisting of carbon. The fillers may be used alone or two types or more can be used together. Among these, silica, especially molten silica is preferable. The average particle size of the inorganic filler is preferably in a range of 0.1 to 80 μm. The average particle size of the inorganic filler can be measured with a laser diffraction type particle size distribution device, for example.

The compounding amount of the filler (especially, the inorganic filler) is preferably 80 parts by weight or less (0 to 80 parts by weight), and especially preferably 0 to 70 parts by weight to 100 parts by weight of the organic resin component.

Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

The film 16 for the backside of a semiconductor can be formed by a common method of preparing a resin composition by mixing a thermosetting resin such as an epoxy resin, a thermoplastic resin such as an acrylic resin as necessary, and a solvent and other additives as necessary and forming the resin composition into a film-like layer.

When the film 16 for the backside of a semiconductor is formed of a resin composition containing a thermosetting resin such as an epoxy resin, the thermosetting resin in the film 16 for the backside of a semiconductor is uncured or is partially cured at the stage before application to a semiconductor wafer. In this case, the thermosetting resin in the film 16 for the backside of a semiconductor is completely cured or almost completely cured after application to a semiconductor wafer (normally when curing a sealing material in a flip-chip bonding step).

Even if the film 16 for the backside of a semiconductor contains a thermosetting resin, the thermosetting resin is not cured or the thermosetting resin is partially cured. Therefore, the gel fraction of the film 16 for the backside of a semiconductor is not particularity limited, and can be appropriately selected from a range of 50% by weight or more for example. The gel fraction is preferably 70% by weight or more, and especially preferably 90% by weight or more. The gel fraction of the film for the backside of a semiconductor can be measured with the following measurement method. If the gel fraction is 50% by weight or more, the winding trace can be reduced.

### <Method for Measuring Gel Fraction>

About 1.0 g of the film for the backside of a semiconductor is sampled and weighed (weight of a sample). The sample is wrapped with a mesh sheet. The wrapped sample is soaked in about 50 ml of ethanol at room temperature for a week. Then, the content insoluble to the solvent (the content of the mesh sheet) is taken from ethanol. The content is dried at 130° C. for about 2 hours, and the dried content insoluble to the solvent is weighed (weight after soaking and drying) to calculate the gel fraction (% by weight) from the following formula (a).

Gel fraction (% by weight)=[(Weight after soaking and drying)/(Weight of sample)]×100 (a)

The gel fraction of the film for the backside of a semiconductor can be controlled by the type and the content of the resin component, the type and the content of the crosslinking agent, the heating temperature, the heating time, and the like.

When the film for the backside of a semiconductor in the present invention is a film that is formed with a resin composition containing a thermosetting resin such as an epoxy resin, adhesion to a semiconductor wafer can be exhibited effectively.

The tensile storage modulus of the non-cured film 16 for the backside of a semiconductor at 23° C. is preferably 0.5 GPa or more, more preferably 0.75 GPa or more, and especially preferably 1 GPa or more. If the tensile storage modulus is 1 GPa or more, the winding trace can be reduced. If the tensile storage modulus is 1 GPa or more, the film for the backside of a semiconductor can be effectively suppressed or prevented from pasting to a support when the semiconductor chip together with the film 16 for the backside of a semiconductor are peeled from the pressure-sensitive adhesive layer 14b of the dicing tape 14, the film 16 for the backside of a semiconductor is placed on the support, and the film 16 is transported, etc. Examples of the support include a top tape and a bottom tape of a carrier tape.

The tensile storage modulus (23° C.) in the uncured portion of the film for the backside of a semiconductor can be controlled by the type and the content of the resin component (a thermoplastic resin and a thermosetting resin), the type and the content of the filler such as a silica filler, and the like.

When the film 16 for the backside of a semiconductor is a laminated film in which a plurality of layers are laminated (when the film for the backside of a semiconductor has a form of laminated layers), an example of the form of laminated layers includes a form of laminated layers consisting of a wafer adhesion layer (a layer containing no coloring agent) and a laser marking layer (a layer containing no coloring agent). Other layers such as an intermediate layer, a light beam shielding layer, a reinforcing layer, a coloring agent layer, a base layer, an electromagnetic wave shielding layer, a heat conducting layer, and a pressure-sensitive adhesive layer may be provided between the wafer adhesion layer and the laser marking layer. The wafer adhesion layer is a layer having excellent adhesion (tackiness) to a wafer and contacting with the backside of the wafer. The laser marking layer is a layer having an excellent laser marking property and is used to perform laser marking on the backside of a semiconductor chip.

The uncured films 16 for the backside of a semiconductor was produced without laminating the films on the dicing tape 14, and the tensile storage modulus was measured using a dynamic viscoelasticity measurement apparatus (Solid Analyzer RS A2) manufactured by Rheometric Scientific FE, Ltd. in tensile mode, sample width 10 mm, sample length 22.5 mm, sample thickness 0.2 mm, frequency 1 Hz, temperature rise rate 10° C./min, under a nitrogen atmosphere, and at a prescribed temperature (23° C.).

The film 16 for the backside of a semiconductor is preferably protected by a separator (a release liner, not shown in the drawings). The separator has a function of protecting the film for the backside of a semiconductor as a protective material until the film is used. The separator is peeled when pasting the semiconductor wafer onto the film for the backside of a semiconductor. Examples of the separator include polyethylene, polypropylene, a plastic film such as polyethylene terephthalate whose surface is coated with a release agent such as a fluorine release agent or a long chain alkylacrylate release agent, and paper. The separator can be formed by a conventionally known method. The thickness of the separator is also not especially limited.

The light transmittance (visible light transmittance) of visible light (having a wavelength of 400 to 800 nm) in the film 16 for the backside of a semiconductor is not especially limited, and is preferably in a range of 20% or less (0 to 20%), more preferably 10% or less (0 to 10%), and especially preferably 5% or less (0 to 5%). When the visible light transmittance of the film 16 for the backside of a semiconductor is larger than 20%, there is a fear that a bad influence may be given to the semiconductor element when the light beam passes. The visible light transmittance (%) can be controlled by the type and the content of the resin component of the film 16 for the backside of a semiconductor, the type and the content of the coloring agent such as a pigment or a dye, the content of the inorganic filler, and the like.

The visible light transmittance (%) of the film for the backside of a semiconductor can be measured as follows. That is, a film for the backside of a semiconductor having a thickness (average thickness) of 20 μm is produced. The film for the backside of a semiconductor is then irradiated with visible light having a wavelength of 400 to 800 nm (a visible light generator “Absorption Spectro Photometer” manufactured by Shimadzu Corporation) at a prescribed intensity, and the intensity of the transmitted visible light beam is measured. The visible light transmittance can be obtained from a change of the intensity before and after the visible light beam transmits through the film for the backside of a semiconductor. It is also possible to obtain the visible light transmittance (%; wavelength: 400 to 800 nm) of the film for the backside of a semiconductor having a thickness of 20 μm from the visible light transmittance (%; wavelength: 400 to 800 nm) of the film for the backside of a semiconductor whose thickness is not 20 μm. The visible light transmittance (%) of the film for the backside of a semiconductor having a thickness of 20 μm is obtained in the present invention. However, the thickness of the film for the backside of a semiconductor according to the present invention is not limited to 20 μm.

The coefficient of moisture absorption of the film 16 for the backside of a semiconductor is preferably low. Specifically, the coefficient of moisture absorption is preferably 1% by weight or less, and more preferably 0.8% by weight or less. By making the coefficient of moisture absorption 1% by weight or less, the laser marking property can be improved. Further, generation of voids between the film 16 for the backside of a semiconductor and the semiconductor element can be suppressed or prevented in a reflow step, for example. The coefficient of moisture absorption is a value calculated from the weight change before and after the film 16 for the backside of a semiconductor are left under an atmosphere of a temperature of 85° C. and a relative humidity of 85% RH for 168 hours. When the film 16 for the backside of a semiconductor are formed of a resin composition containing a thermosetting resin, the coefficient of moisture absorption is a value obtained the films for the backside of a semiconductor after thermal curing are left under an atmosphere of a temperature of 85° C. and a relative humidity of 85% RH for 168 hours. The coefficient of moisture absorption can be adjusted by changing the added amount of the inorganic filler, for example.

The ratio of the volatile component of the film 16 for the backside of a semiconductor is preferably small. Specifically, the weight decrease rate (ratio of the weight decrease amount) of the film 16 for the backside of a semiconductor after a heat treatment is preferably 1% by weight or less, and more preferably 0.8% by weight or less. The condition of the heating treatment is a heating temperature of 250° C. and a heating time of 1 hour, for example. By making the weight decrease rate 1% by weight or less, the laser marking property can be improved. The generation of cracks in the flip-chip type semiconductor device can be suppressed or prevented in a reflow step, for example. The weight decrease rate can be adjusted by adding an inorganic substance that can decrease the generation of cracks during a lead free solder reflow, for example. When the film 16 for the backside of a semiconductor is formed with a resin composition containing a thermosetting resin, the weight decrease rate means a value obtained when the film for the backside of a semiconductor after thermal curing is heated under conditions of a heating temperature of 250° C. and a heating time of 1 hour.

The thickness of the film 16 for the backside of a semiconductor is not especially limited. However, it can be appropriately selected from a range of about 2 μm to 200 μm. The thickness is preferably about 4 μm to 160 μm, more preferably about 6 μm to 100 μm, and especially preferably about 10 μm to 80 μm.

### (Dicing Tape)

The dicing tape 14 has a configuration in which the pressure-sensitive adhesive layer 14b is formed on the base 14a. As described above, the dicing tape 14 may have a configuration in which the base 14a and the pressure-sensitive adhesive layer 14b are laminated. The base can be used as a support base body of the pressure-sensitive adhesive layer, and the like. The base 14a preferably has radiation transparency. Examples of the base 14a include appropriate thin materials including paper bases such as paper; fiber bases such as cloth, unwoven cloth, felt, and net; metal bases such as a metal foil and a metal plate; plastic bases such as a plastic film and sheet; rubber bases such as a rubber sheet; foams such as a foamed sheet, and laminated bodies of these (especially laminated bodies of a plastic base and other bases and laminated bodies of plastic films or sheets). In the present invention, a plastic base such as a plastic film or sheet can be preferably used as the base. Examples of the material of such a plastic base include olefin resins such as polyethylene (PE), polypropylene (PP), and an ethylene-propylene copolymer; copolymers having ethylene as a monomer component such as a ethylene vinyl acetate copolymer (EVA), an ionomer resin, a ethylene-(meth)acrylate copolymer, and an ethylene-(meth)acrylate (random, alternating) copolymer; polyesters such as polyethylene terephthalate (PET), polyethylene naphthalate (PEN), and polybutylene terephthalate (PBT); an acrylic resin; polyvinyl chloride (PVC); polyurethane; polycarbonate; polyphenylene sulfide (PPS); amide resins such as polyamide (nylon) and fully aromatic polyamide (aramid); polyether ether ketone (PEEK); polyimide; polyetherimide; polyvinylidene chloride; ABS (acrylonitrile-butadiene-styrene copolymer); a cellulose resin; a silicone resin; and a fluororesin.

Further, the material of the base 14a includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 14b and the film 16 for the backside of a semiconductor are reduced by thermally shrinking the base 14a after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base 14a in order to improve adhesiveness, holding properties, etc. with the adjacent layer.

The same type or different types can be appropriately selected and used as the base 14a, and several types can be blended and used as necessary. The base 14a may be a single layer or a multilayer consisting of two types or more layers.

The thickness of the base 14a (total thickness in the case of a laminated body) is not especially limited, and can be appropriately selected according to the strength, flexibility, purpose of use, and the like. For example, the thickness is generally 1000 μm or less (1 to 1000 μm, for example), preferably 10 to 500 μm, more preferably 20 to 300 μm, and especially preferably about 30 to 200 μm. However, the thickness is not limited to these ranges.

The base 14a may contain various additives such as a coloring agent, a filler, a plasticizer, an anti-aging agent, an antioxidant, a surfactant, and a flame retardant as long as the effects of the present invention are not deteriorated.

The pressure-sensitive adhesive layer 14b is formed with a pressure-sensitive adhesive, and has adherability. The pressure-sensitive adhesive is not especially limited, and can be appropriately selected among known pressure-sensitive adhesives. Specifically, known pressure-sensitive adhesives (refer to Japanese Patent Application Laid-Open Nos. 56-61468, 61-174857, 63-17981, and 56-13040, for example) such as a pressure-sensitive adhesive having the above-described characteristics can be appropriately selected from an acrylic pressure-sensitive adhesive, a rubber pressure-sensitive adhesive, a vinylalkylether pressure-sensitive adhesive, a silicone pressure-sensitive adhesive, a polyester pressure-sensitive adhesive, a polyamide pressure-sensitive adhesive, a urethane pressure-sensitive adhesive, a fluorine pressure-sensitive adhesive, a styrene-diene block copolymer pressure-sensitive adhesive, and a creep property improved pressure-sensitive adhesive in which a hot-melt resin having a melting point of about 200° C. or less is compounded in these pressure-sensitive adhesives. A radiation curing type pressure-sensitive adhesive (or an energy ray curing type pressure-sensitive adhesive) and a thermally expandable pressure-sensitive adhesive can also be used as the pressure-sensitive adhesive. The pressure-sensitive adhesives can be used alone or two types or more can be used together.

An acrylic pressure-sensitive adhesive and a rubber pressure-sensitive adhesive can be suitably used as the pressure-sensitive adhesive, and especially an acrylic pressure-sensitive adhesive is suitable. An example of the acrylic pressure-sensitive adhesive is an acrylic pressure-sensitive adhesive having an acrylic polymer, in which one type or two types or more of alkyl (meth)acrylates are used as a monomer component, as a base polymer.

Examples of alkyl (meth)acrylates in the acrylic pressure-sensitive adhesive include methyl (meth)acrylate, ethyl (meth)acrylate, propyl (meth)acrylate, isopropyl (meth)acrylate, butyl(meth)acrylate, isobutyl(meth)acrylate, s-butyl (meth)acrylate, t-butyl (meth)acrylate, pentyl (meth)acrylate, hexyl (meth)acrylate, heptyl (meth)acrylate, octyl (meth)acrylate, 2-ethylhexyl (meth)acrylate, isooctyl (meth)acrylate, nonyl(meth)acrylate, isononyl(meth)acrylate, decyl (meth)acrylate, isodecyl (meth)acrylate, undecyl (met)acrylate, dodecyl(meth)acrylate, tridecyl(meth)acrylate, tetradecyl (meth)acrylate, pentadecyl (meth)acrylate, hexadecyl(meth)acrylate, heptadecyl(meth)acrylate, octadecyl (meth)acrylate, nonadecyl (meth)acrylate, and eicosyl (meth)acrylate. Alkyl (meth)acrylates having an alkyl group of 4 to 18 carbon atoms is suitable. The alkyl group of alkyl (meth)acrylates may be any of linear or branched chain.

The acrylic polymer may contain units that correspond to other monomer components that is copolymerizable with alkyl (meth)acrylates described above (copolymerizable monomer component) for reforming cohesive strength, heat resistance, and crosslinking property, as necessary. Examples of such copolymerizable monomer components include carboxyl group-containing monomers such as (meth)acrylic acid (acrylic acid, methacrylic acid), carboxyethyl acrylate, carboxypentyl acrylate, itaconic acid, maleic acid, fumaric acid, and crotonic acid; acid anhydride group-containing monomers such as maleic anhydride and itaconic anhydride; hydroxyl group-containing monomers such as hydroxyethyl (meth)acrylate, hydroxypropyl (meth)acrylate, hydroxybutyl (meth)acrylate, hydroxyhexyl (meth)acrylate, hydroxyoctyl (meth)acrylate, hydroxydecyl (meth)acrylate, hydroxylauryl (meth)acrylate, and (4-hydroxymethylcyclohexyl)methyl methacrylate; sulfonate group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphate group-containing monomers such as 2-hydroxyethylacryloylphosphate; (N-substituted) amide monomers such as (meth)acrylamide, N,N-dimethyl(meth)acrylamide, N-butyl(meth)acrylamide, N-methylol(meth)acrylamide, and N-methylolpropane(meth)acrylamide; aminoalkyl (meth)acrylate monomers such as aminoethyl (meth)acrylate, N,N-dimethlaminoethyl (meth)acrylate, and t-butylaminoethyl (meth)acrylate; alkoxyalkyl (meth)acrylate monomers such as methoxyethyl (meth)acrylate and ethoxyethyl (meth)acrylate; cyanoacrylate monomers such as acrylonitrile and methacrylonitrile; epoxy group-containing acrylic monomers such as glycidyl(meth)acrylate; styrene monomers such as styrene and α-methylstyrene; vinylester monomers such as vinyl acetate and vinyl propionate; olefin monomers such as isoprene, butadiene, and isobutylene; vinylether monomers such as vinylether; nitrogen-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, and N-vinylcaprolactam; maleimide monomers such as N-cyclohexylmaleimide, N-isopropylmaleimide, N-laurylmaleimide, and N-phenylmaleimide; itaconimide monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide monomers such as N-(meth)acryloyloxymethylene succinimide, N-(meth)acryloyl-6-oxyhexamethylene succinimide, and N-(meth)acryloyl-8-oxyoctamethylene succinimide; glycol acrylester monomers such as polyethylene glycol (meth)acrylate, polypropylene glycol (meth)acrylate, metoxyethylene glycol (meth)acrylate, and metoxypolypropylene glycol(meth)acrylate; acrylate monomers having a heterocyclic ring, a halogen atom, a silicon atom, and the like such as tetrahydrofurfuryl (meth)acrylate, fluorine (meth)acrylate, and silicone (meth)acrylate; and polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxyacrylate, polyesteracrylate, urethaneacrylate, divinylbenzene, butyl di(meth)acrylate, and hexyl di(meth)acrylate. One type or two types or more of these copolymerizable monomer components can be used.

When a radiation curing type pressure-sensitive adhesive (or an energy ray curing type pressure-sensitive adhesive) is used as the pressure-sensitive adhesive, examples of the radiation curing type pressure-sensitive adhesive (composition) include an internal radiation curing type pressure-sensitive adhesive having a polymer with a radical reactive carbon-carbon double bond in the polymer side chain, the main chain, or the ends of the main chain as a base polymer and a radiation curing type pressure-sensitive adhesive in which ultraviolet-ray curing-type monomer component and oligomer component are compounded in the pressure-sensitive adhesive. When a thermally expandable pressure-sensitive adhesive is used as the pressure-sensitive adhesive, examples thereof include a thermally expandable pressure-sensitive adhesive containing a pressure-sensitive adhesive and a foaming agent (especially, a thermally expandable microsphere).

The pressure-sensitive adhesive layer 14b of the present invention may contain various additives such as a tackifier, a coloring agent, a thickener, an extender, a filler, a plasticizer, an anti-aging agent, an antioxidant, a surfactant, and a crosslinking agent as long as the effects of the present invention are not deteriorated.

The crosslinking agent is not especially limited, and known crosslinking agents can be used. Specific examples of the crosslinking agent include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent, and an isocyanate crosslinking agent and an epoxy crosslinking agent are preferable. The crosslinking agents can be used alone or two types or more can be used together. The used amount of the crosslinking agent is not especially limited.

Examples of the isocyanate crosslinking agent include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethane diisocyanate, and xylylene diisocyanate. A trimethylolpropane/tolylene diisocyanate trimeric adduct (Coronate L manufactured by Nippon Polyurethane Industry Co., Ltd.), and a trimethylolpropane/hexamethylene diisocyanate trimeric adduct (Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerithritol polyglycidylether, polyglycerol polyglycidylether, sorbitan polyglycidylether, trimethylolpropane polyglycidylether, diglycidyl adipate, o-diglycidyl phthalate, triglycidyl-tris(2-hydroxyethyl)isocyanurate, resorcin diglycidylether, bisphenol-S-diglycidylether; and an epoxy resin having two or more epoxy groups in a molecule.

In the present invention, a crosslinking treatment can be performed by irradiation with an electron beam, an ultraviolet ray, or the like instead of using the crosslinking agent or in addition to the use of the crosslinking agent.

The pressure-sensitive adhesive layer 14b can be formed by a common method of forming a sheet-like layer by mixing the pressure-sensitive adhesive with a solvent, other additives, and the like as necessary. Specifically, the pressure-sensitive adhesive layer 14b can be produced by a method of applying the pressure-sensitive adhesive or a mixture containing the pressure-sensitive adhesive, a solvent and other additives to the base 14a, a method of forming the pressure-sensitive adhesive layer 14b by applying the above-described mixture to an appropriate separator (release paper, for example), and transferring (adhering) the resultant onto the base 14a, for example.

The thickness of the pressure-sensitive adhesive layer 14b is not especially limited, and is about 5 to 300 μm (preferably 5 to 200 μm, more preferably 5 to 100 μm, and especially preferably 7 to 50 μm). When the thickness of the pressure-sensitive adhesive layer 14b is in the above-described range, adequate adhesive power can be exhibited. The pressure-sensitive adhesive layer 14b may be a single layer or a plurality of layers.

The thickness of the film 13 with attached dicing tape for the backside of a flip-chip type semiconductor (total thickness of the film for the backside of a semiconductor and the dicing tape 14 consisting of the base 14a and the pressure-sensitive adhesive layer 14b) can be selected from a range of 7 to 11300 μm, and is preferably 17 to 1600 μm, and more preferably 28 to 1200 μm.

By controlling the ratio between the thickness of the film for the backside of a flip-chip type semiconductor and the thickness of the pressure-sensitive adhesive layer of the dicing tape and the ratio between the thickness of the film for the backside of a flip-chip type semiconductor and the thickness of the dicing tape (total thickness of the base and the pressure-sensitive adhesive layer) in the film 13 with attached dicing tape for the backside of a flip-chip type semiconductor, the dicing property in a dicing step, the pickup property in a pickup step, and the like can be improved, and the film 13 with attached dicing tape for the backside of a flip-chip type semiconductor can be effectively used from the dicing step of a semiconductor wafer to the flip-chip bonding step of a semiconductor chip.

### (Separator)

Polyethylene terephthalate (PET), polyethylene, polypropylene; and a plastic film, paper, etc. in which their surfaces are coated with a release agent such as a fluorine based release agent and a long-chain alkylacrylate based release agent can be used as the separator 12.

The thickness of the separator 12 is preferably 5 μm to 500 μm, and more preferably 10 μm to 200 μm. If the thickness of the separator 12 is 5 μm or more, the separator 12 can be stably manufactured into a tape, and if the thickness is 500 μm or less, the separator 12 can be released in a controlled manner.

### (Method for Manufacturing Film for Semiconductor Device)

The method for manufacturing a semiconductor device according to the present embodiment will be explained using the film for a semiconductor device shown in FIG. 1 as an example.

First, the film 16 for the backside of a flip-chip type semiconductor is formed on the entire surface of one side of the separator 12. A specific example of the formation method is a method of directly coating the separator 12 with a resin composition solution for forming the film 16 for the backside of a flip-chip type semiconductor and drying the resin composition solution.

Next, a cut Y1 (not shown in the drawing) is made from the film 16 for the backside of a flip-chip type semiconductor just deep enough for the cut to reach the separator 12. The shape of the cut Y1 in planar view is a shape corresponding to the shape of the semiconductor wafer for pasting (a circular shape in the drawing). The cut can be made using a mold or a cutting blade.

Then, the portion outside of the cut made in the film 16 for the backside of a flip-chip type semiconductor is peeled for removal. Accordingly, a plurality of the films 16 for the backside of a flip-chip type semiconductor are laminated on the separator 12 at a prescribed interval.

Next, the dicing tape 14 is pasted to the entire surface of the separator 12 from the side of the surface where the films 16 for the backside of a flip-chip type semiconductor are laminated so that the dicing tape 14 covers the films 16 for the backside of a flip-chip type semiconductor. The dicing tape 14 is pasted so that the pressure-sensitive adhesive layer 14b of the dicing tape 14 and the films 16 for the backside of a flip-chip type semiconductor or the separator 12 serve as a pasting surface.

Next, a cut Y2 (not shown in the drawing) is made from the base 14a of the dicing tape 14 just deep enough for the cut to reach the separator 12. The cut Y2 has a circular shape, its center is the same as that of the film 16 for the backside of a flip-chip type semiconductor, and its diameter can be the same as or larger than that of the film 16 for the backside of a flip-chip type semiconductor. When the diameter of the cut is larger than that of the film 16 for the backside of a flip-chip type semiconductor as in the present embodiment, a dicing ring can be pasted to the excess portion. The cut can be made using a mold or a cutting blade.

A cut Y3 (not shown in the drawing) is made outside the cut Y2 in the width direction of the separator 12 along the long sides. The cut Y3 is made from the base 14a of the dicing tape 14 just deep enough for the cut to reach the separator 12. The cut Y3 can be made so that the cut outside the portion where the films 16 for the backside of a flip-chip type semiconductor are arranged is narrower than the cut outside the portion where the films 16 for the backside of a flip-chip type semiconductor are not arranged. Specifically, the cut Y3 outside the portion where the films 16 for the backside of a flip-chip type semiconductor are arranged can have an arc shape with a constant distance from the cut Y2, and the cut Y3 outside the portion where the films 16 for the backside of a flip-chip type semiconductor are not arranged can be a straight line connecting one end of the arc-shaped portion to another end of the arc-shaped portion in the long-side direction.

Then, the dicing tape 14 outside of the cut Y2 and inside the cut Y3 is peeled from the separator 12 to be removed.

Accordingly, the film 10 for a semiconductor device shown in FIG. 1 can be obtained.

### (Method for Manufacturing Semiconductor Device)

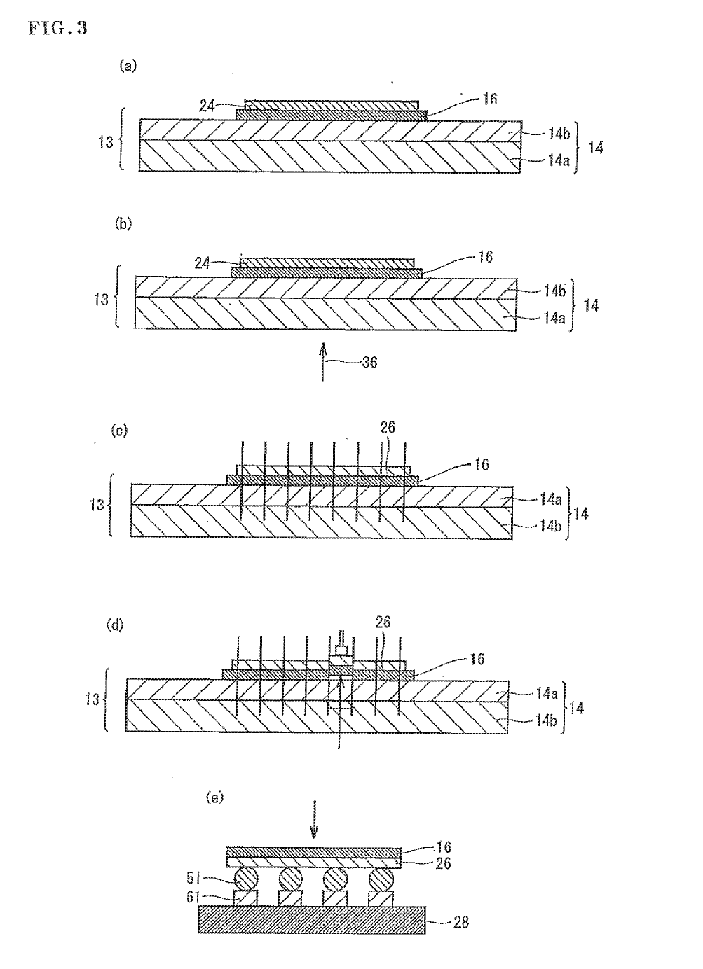

The method for manufacturing a semiconductor device according to the present embodiment will be explained below by referring to FIGS. 3(a) to 3 (e). FIGS. 3(a) to 3 (e) are schematic cross sections showing the method for manufacturing a semiconductor device using the film 10 for a semiconductor device.

The method for manufacturing a semiconductor device according to the present embodiment has at least a step of peeling the film 13 with attached dicing tape for the backside of a flip-chip type semiconductor from the film 10 for a semiconductor device, a step of pasting a semiconductor wafer 24 onto the film 16 for the backside of a flip-chip type semiconductor of the peeled film 13 with attached dicing tape for the backside of a flip-chip type semiconductor, a step of performing laser marking on the film 16 for the backside of a flip-chip type semiconductor, a step of dicing the semiconductor wafer 24 to form a semiconductor element 26, a step of peeling the semiconductor element 26 together with the film 16 for the backside of a flip-chip type semiconductor from the pressure-sensitive adhesive layer 14b, and a step of flip-chip bonding the semiconductor element 26 onto an adherend 28.

### [Peeling Step]

The film 13 with attached dicing tape for the backside of a flip-chip type semiconductor is peeled from the film 10 for a semiconductor device.

### [Mounting Step]

As shown in FIG. 3(a), the semiconductor wafer 24 is pasted onto the film 16 for the backside of a flip-chip type semiconductor of the film 13 with attached dicing tape for the backside of a flip-chip type semiconductor, and the semiconductor wafer 24 is held for adhesion to be fixed. The film 16 for the backside of a flip-chip type semiconductor at this time is in an uncured state (including a semi-cured state). Further, the film 13 with attached dicing tape for the backside of a flip-chip type semiconductor is pasted to the backside of the semiconductor wafer 24. The backside of the semiconductor wafer 24 means the surface opposite to the circuit surface (also referred to as anon-circuit surface, a non-electrode formation surface, etc.) The pasting method is not particularly limited; however, a method of pasting while pressing is preferable. The pasting while pressing can be normally performed while pressing by a pressing means such as a press roll.

Next, baking (heating) is performed as necessary in order to strengthen the fixing of the film 16 for the backside of a flip-chip type semiconductor to the semiconductor wafer 24. The baking is performed at 80° C. to 150° C. for 0.1 hour to 24 hours for example.

### [Laser Marking Step]

Next, as shown in FIG. 3 (b), laser marking is performed on the film 16 for the backside of a flip-chip type semiconductor using a laser 36 for laser marking from the dicing tape 14 side. The condition of laser marking is not especially limited. However, it is preferable to irradiate the film 16 for the backside of a flip-chip type semiconductor with a laser beam [wavelength: 532 nm] having the intensity of 0.3 W to 2.0 W. Further, it is preferable to irradiate so that the process depth (depth) becomes 2 μm or more. The upper limit of the process depth is not especially limited. However, it can be selected from a range of 2 μm to 25 μm, it is preferably 3 μm or more (3 μm to 20 μm), and more preferably 5 μm or more (5 μm to 15 μm). The condition of laser marking is set to be within the above-described ranges to exhibit excellent laser marking properties.

Further, the laser processing properties of the film 16 for the backside of a flip-chip type semiconductor can be controlled by the types and the content of the constituting resin components, the type and the content of the coloring agent, the type and the content of the crosslinking agent, the type and the content of the filler, etc.

### [Dicing Step]

As shown in FIG. 3 (c), dicing of the semiconductor wafer 24 is performed. With this operation, the semiconductor wafer 24 is cut into individual pieces (cut into small pieces) having a prescribed size, and a semiconductor chip 26 is manufactured. The dicing is performed from the circuit surface side of the semiconductor wafer 24 by a normal method, for example. For example, a cutting method called full cut in which cutting is performed up to the dicing tape 14 can be adopted in this step. The dicing apparatus used in this step is not especially limited, and a conventionally known apparatus can be used. Because the semiconductor wafer 24 is adhered and fixed with excellent adhesion by the film 13 with attached dicing tape for the backside of a flip-chip type semiconductor, chip cracks and chip fly can be suppressed and damages to the semiconductor wafer 24 can also be suppressed.

When expanding the film 13 with attached dicing tape for the backside of a flip-chip type semiconductor, a conventionally known expanding apparatus can be used. The expanding apparatus has a donut-shaped outer ring that can push down the film 13 with attached dicing tape for the backside of a flip-chip type semiconductor through a dicing ring and an inner ring that has a smaller diameter than the outer ring and that supports the dicing tape-integrated film for the backside of a semiconductor. With this expanding step, generation of damages caused by the contact between adjacent semiconductor chips can be prevented in the pickup step described later.

### [Pickup Step]

The semiconductor chip 26 is peeled from the dicing tape 14 together with the film 16 for the backside of a flip-chip type semiconductor by performing pickup of the semiconductor chip 26 as shown in FIG. 3(d) to collect the semiconductor chip 26 that is adhered and fixed to the film 13 with attached dicing tape for the backside of a flip-chip type semiconductor. The pickup method is not especially limited, and various conventionally known methods can be adopted. An example of the method is a method of pushing up an individual semiconductor chip 26 from the side of the base 14a of the film 13 with attached dicing tape for the backside of a flip-chip type semiconductor with a needle and picking up the pushed semiconductor chip 26 with a pickup apparatus.

When a radiation curing type pressure-sensitive adhesive (or an energy beam curing type pressure-sensitive adhesive) is used as the pressure-sensitive adhesive constituting the pressure-sensitive adhesive layer 14b, it is preferably to irradiate the layer with an ultraviolet ray to perform pickup. With this, pickup can be performed easily. Especially, in the laser marking step, air bubbles may be generated at the interface between the film 16 for the backside of a flip-chip type semiconductor and the pressure-sensitive adhesive layer 14b. Because of that, a radiation curing type pressure-sensitive adhesive (or an energy beam curing type pressure-sensitive adhesive) is used as the pressure-sensitive adhesive constituting the pressure-sensitive adhesive layer 14b, the pressure-sensitive adhesive layer 14b and the film 16 for the backside of a flip-chip type semiconductor are firmly pasted together in the laser marking step to suppress the generation of air bubbles. Then, it is preferable to irradiate the layer with radiation (or an energy beam) to lower the adhesive power and to perform pickup easily during pickup.

The backside of the semiconductor chip 26 that is picked up is protected by the film 16 for the backside of a flip-chip type semiconductor.

### [Flip-Chip Connecting Step]

As shown in FIG. 3(e), the semiconductor chip 26 that is picked up is fixed to an adherend such as a substrate by a flip-chip bonding method (flip-chip mounting method). Specifically, the semiconductor chip 26 is fixed to an adherend 28 by a normal method in a form that the circuit surface (also referred to as the surface, a circuit pattern forming surface, or an electrode forming surface) of the semiconductor chip 26 faces the adherend 28. The semiconductor chip 26 can be fixed to the adherend 28 while securing electrical conduction of the semiconductor chip 26 with the adherend 28 by contacting and pressing a bump 51 formed on the circuit surface side of the semiconductor chip 26 to a conductive material 61 such as solder for bonding that is adhered to a connection pad of the adherend 28 and melting the conductive material (a flip-chip bonding step). At this time, a space is formed between the semiconductor chip 26 and the adherend 28, and the distance of the space is generally about 30 to 300 μm. After flip-chip bonding (flip-chip connection) of the semiconductor chip 26 onto the adherend 28, it is important to wash the facing surface and the space between the semiconductor chip 26 to the adherend 28 and to seal the space by filling the space with a sealing material such as a sealing resin.

Various substrates such as a lead frame and a circuit board (a wiring circuit board, for example) can be used as the adherend 28. The material of the substrate is not especially limited, and examples thereof include a ceramic substrate and a plastic substrate. Examples of the plastic substrate include an epoxy substrate, a bismaleimide triazine substrate, and a polyimide substrate.

The material of the bump and the conductive material in the flip-chip bonding step are not especially limited, and examples thereof include solders (alloys) of a tin-lead metal material, a tin-silver metal material, a tin-silver-copper metal material, a tin-zinc metal material, and a tin-zinc-bismuth metal material, a gold metal material, and a copper metal material.

In the flip-chip bonding step, the bump of the circuit surface side of the semiconductor chip 26 and the conductive material on the surface of the adherend 28 are connected by melting the conductive material. The temperature when the conductive material is molten is normally about 260° C. (250 to 300° C., for example). The dicing tape-integrated film for the backside of a semiconductor of the present invention can have heat resistance so that it can resist a high temperature in the flip-chip bonding step by forming the film for the backside of a semiconductor with an epoxy resin, or the like.

In this step, the facing surface (an electrode forming surface) and the space between the semiconductor chip 26 and the adherend 28 are preferably washed. The washing liquid that is used in washing is not especially limited, and examples thereof include an organic washing liquid and a water washing liquid. The film for the backside of a semiconductor in the dicing tape-integrated film for the backside of a semiconductor of the present invention has solvent resistance to the washing liquid, and does not substantially have solubility in these washing liquids. Because of that, various washing liquids can be used as the washing liquid, and washing can be performed by a conventional method without requiring a special washing liquid.

Next, a sealing step is performed to seal the space between the flip-chip bonded semiconductor chip 26 and the adherend 28. The sealing step is performed using a sealing resin. The sealing condition is not especially limited. Thermal curing (reflow) of the sealing resin is performed normally by heating the sealing resin at 175° C. for 60 to 90 seconds. However, the present invention is not limited to this, and curing can be performed at 165 to 185° C. for a few minutes, for example. In the heat process of this step, thermal curing of not only the sealing resin but also the film 16 for the backside of a flip-chip type semiconductor may be performed at the same time. In this case, it is not necessary to newly add a step for thermally curing the film 16 for the backside of a flip-chip type semiconductor. However, the present invention is not limited to this example, a step of thermally curing the film 16 for the backside of a flip-chip type semiconductor may be performed separately before the sealing resin is thermally cured.

The sealing resin is not especially limited as long as it is a resin having insulation properties, and can be appropriately selected from sealing materials such as a known sealing resin. However, an insulating resin having elasticity is preferable. Examples of the sealing resin include a resin composition containing an epoxy resin. Examples of the epoxy resin include epoxy resins described above. The sealing resin with a resin composition containing an epoxy resin may contain a thermosetting resin such as a phenol resin other than the epoxy resin, a thermoplastic resin, and the like as a resin component besides the epoxy resin. The phenol resin can also be used as a curing agent for the epoxy resin, and examples of the phenol resin include the above-described phenol resins.

In the above-described embodiment, a case is explained in which the space between a semiconductor chip 26 and an adherend 28 is sealed by filling the space with liquid sealant (a sealing resin, etc.). However, the present invention is not limited to this example, and a sheet resin composition may be used. As the method of sealing the space between the semiconductor chip and the adherend using a sheet rein composition, conventionally known methods described in JP-A-2001-332520, etc. can be adopted. Therefore, the detailed explanation of the method is omitted.

In the above-described embodiment, the film 16 for the backside of a flip-chip type semiconductor was diced and thermally cured. However, the present invention is not limited to this example, and the film 16 for the backside of a flip-chip type semiconductor may be thermally cured before the dicing step. In this case, an increase of the peel strength between the dicing tape and the film for the backside of a flip-chip type semiconductor is suppressed even if the film with integrated dicing tape for the backside of a semiconductor is heated in the thermally curing step. Therefore, poor peeling is suppressed in the pickup step.

After the sealing step is performed, a heat treatment (a reflow step that is performed after laser marking) may be performed as necessary. The condition of the heat treatment is not especially limited, and the heat treatment can be performed according to the standards by JEDEC Solid State Technology Association. For example, the heat treatment can be performed at a temperature (upper limit) of 210 to 270° C. and a period of 5 to 50 seconds. With this step, a semiconductor package can be mounted on a substrate such as a mother board.

Because the semiconductor device that is manufactured using the dicing tape-integrated film for the backside of a semiconductor of the present invention is a semiconductor device that is mounted by a flip-chip mounting method, the semiconductor device has a shape thinner and smaller than a semiconductor device that is mounted by a die bonding mounting method. Because of this, the semiconductor device can be suitably used as various electronic apparatuses and electronic parts or materials and members thereof. Specific examples of the electronic apparatus in which the flip-chip mounted semiconductor device of the present invention can be used include a portable phone, PHS, a small computer such as PDA (personal digital assistant), a notebook personal computer, Netbook (trademark), or a wearable computer, a small electronic apparatus in which a portable phone and a computer are integrated, Digital Camera (trademark), a digital video camera, a small television, a small game machine, a small digital audio player, an electronic organizer, an electronic dictionary, an electronic apparatus terminal for an electronic book, and a mobile electronic apparatus (portable electronic apparatus) such as a small digital type clock or watch. Examples of the electronic apparatus also include an electronic apparatus other than a mobile type apparatus (i.e., a stationary apparatus) such as a desktop personal computer, a flat-panel television, an electronic apparatus for recording and playing such as a hard disc recorder or a DVD player, a projector, or a micromachine. Examples of the electronic parts or materials and members of the electronic apparatus and electronic parts include a component of CPU and components of various recording apparatuses such as a memory and a hard disk.

### EXAMPLES

Hereinafter, preferred working examples of the present invention will be demonstrated in detail. However, materials, blend amounts and others that are described in the examples do not limit the scope of this invention as far as the claims do not include a restricted recitation thereabout. Hereinafter, the word “part(s)” means part(s) by weight.

### <Production of Film for Backside of Semiconductor>

53 parts of an epoxy resin (trade name “HP-4700” manufactured by DIC Corporation), 69 parts of a phenol resin (trade name “MEH-7851H” manufactured by Meiwa Plastic Industries, Ltd.), 153 parts of spherical silica (trade name “SE-2050-MCV” manufactured by Admatechs), and 7 parts of dye (trade name “ORIPAS B-35” manufactured by Orient Chemical Industries Co., Ltd.) to 100 parts of an acrylic acid ester polymer containing butylacrylate-acrylonitrile as main component (trade name “SG-P3” manufactured by Nagase ChemteX Corporation) were dissolved in methylethylketone, and the solution was adjusted to have a concentration of 23.6% by weight.

The solution of the adhesive compositions was applied onto a release-treated film of a silicone release-treated polyethylene terephthalate film having a thickness of 50 μm as a release liner, and the resultant was dried at 130° C. for 2 minutes to produce a film A for the backside of a semiconductor having a thickness of 25 μm.

### <Measurement of Gel Fraction of Film for Backside of Semiconductor>

About 1.0 g of the film A for the backside of a semiconductor was sampled and weighed (weight of a sample). The sample was wrapped with a mesh sheet. The wrapped sample was soaked in about 50 ml of ethanol at room temperature for a week. Then, the content insoluble to the solvent (the content of the mesh sheet) was taken from ethanol. The content was dried at 130° C. for about 2 hours, and the dried content insoluble to the solvent was weighed (weight after soaking and drying) to calculate the gel fraction (% by weight) from the following formula (a). As a result, the gel fraction was 95% by weight.

Gel fraction (% by weight)=[(Weight after soaking and drying)/(Weight of sample)]×100 (a)

<Measurement of tensile storage modulus of film for backside of semiconductor at 23° C.>

The film A for the backside of a semiconductor was produced without laminating a dicing tape, and the modulus of the film A for the backside of a semiconductor was measured for a sample having a width of 10 mm, a length of 22.5 mm, and a thickness of 0.2 mm with a tensile mode at a frequency of 1 Hz, a rising temperature speed of 10° C./min, and a prescribed temperature of 23° C. under a nitrogen atmosphere using a solid viscoelastic measurement apparatus (trade name “Solid Analyzer RS A2” manufactured by Rheometric Scientific, Inc.). The obtained value was a tensile storage modulus E′. As a result, the tensile storage modulus at 23° C. was 4.1 GPa.

### <Preparation of Dicing Tape>

Trade name “V-8AR” manufactured by Nitta Denko Corporation was prepared as a dicing tape A. “V-8AR” is a dicing tape consisting of a base (material:vinylchloride) having a thickness of 65 μm and a pressure-sensitive adhesive layer having a thickness of 10 μm.

### <Preparation of Separator>

Trade name “Diafoil MRA38” manufactured by Mitsubishi Plastics Inc. was prepared as a separator A. The material of the separator A was polyethylene terephthalate, and the thickness thereof was 38 μm.

### <Production of Film for Backside of Semiconductor>

The separator A, the dicing tape A, and the film A for the backside of a semiconductor were used to produce the film for a semiconductor device shown in FIGS. 1 and 2 with the method described in the embodiment. Each film for a semiconductor device of Examples 1 to 3 and Comparative Examples 1 and 2 was produced only by changing the dimensions of A to H. The dimensions of A to H for each example and each comparative example are as follows.

### Example 1

A: 390 mm

B: 370 mm

C: 330 mm

D: 380 mm

E: 30 mm

F: 10 mm

G: 9.5 mm

H: 45 mm

Number of the films with attached dicing tape for the backside of a flip-chip type semiconductor pasted to the separator A: 50 films

### Example 2

A: 390 mm

B: 370 mm

C: 330 mm

D: 380 mm

E: 30 mm

F: 10 mm

G: 5 mm

H: 45 mm

Number of the films with attached dicing tape for the backside of a flip-chip type semiconductor pasted to the separator A: 50 films

### Example 3

A: 390 mm

B: 370 mm

C: 330 mm

D: 380 mm

E: 30 mm

F: 10 mm

G: 2 mm

H: 45 mm

Number of the films with attached dicing tape for the backside of a flip-chip type semiconductor pasted to the separator A: 50 films

### Comparative Example 1

A: 390 mm

B: 370 mm

C: 330 mm

D: 380 mm

E: 30 mm

F: 10 mm

G: 1 mm

H: 45 mm

Number of the films with attached dicing tape for the backside of a flip-chip type semiconductor pasted to the separator A: 50 films

### Comparative Example 2

A: 390 mm

B: 370 mm

C: 330 mm

D: 380 mm

E: 30 mm

F: 10 mm

G: 0 mm

H: 45 mm

Number of the films with attached dicing tape for the backside of a flip-chip type semiconductor pasted to the separator A: 50 films

### (Evaluation of Winding Trace)

Each of the films for a semiconductor device of Examples and Comparative Examples was wound around a winding core having a diameter of 8.9 cm. The winding tension applied to the film for a semiconductor device was 15 N/m. The wound film with the core was stored at room temperature (25° C.) for a week.

After being stored, the first film with attached dicing tape for the backside of a flip-chip type semiconductor from the beginning of winding (the film closest to the winding core) was peeled. Then, a maximum depth of the winding trace on the film for the backside of a semiconductor of the peeled film with attached dicing tape for the backside of a flip-chip type semiconductor was measured using a contact profilometer. The case in which the maximum depth of the winding trace was 1 μm or less was evaluated as ◯, and the case in which the maximum depth of the winding trace exceeds 1 μm was evaluated as X. The results are shown in Table 1.

TABLE 1

| | | | | Compara- | Compara- |
|---|---|---|---|---|---|
| | Exam- | Exam- | Exam- | tive | tive |
| | ple 1 | ple 2 | ple 3 | Example 1 | Example 2 |
| Maximum Depth of | 0.6 | 0.6 | 0.7 | 2 | 2 |
| Winding Trace (μm) | | | | | |
| Evaluation of | ◯ | ◯ | ◯ | X | X |
| Winding Trace | | | | | |

What is claimed is:

1. A film for a semiconductor device having:
a long separator,
a plurality of films with attached dicing tape for the backside of a flip-chip type semiconductor arranged on the separator in a row at a prescribed interval, and
an outer sheet arranged outside the film with attached dicing tape for the backside of a flip-chip type semiconductor and laminated on the separator so as to include long sides of the separator; wherein
the film with attached dicing tape for the backside of a flip-chip type semiconductor has a dicing tape and a film for the backside of a flip-chip type semiconductor laminated on the dicing tape not to protrude from the dicing tape, and
the film with attached dicing tape for the backside of a flip-chip type semiconductor are laminated on the separator so that the separator and the film for the backside of a flip-chip type semiconductor serve as a pasting surface; and
when the length of the narrowest portion of the outer sheet is set to G and the length from the long side of the separator to the dicing tape is set to F, G is within the range from 0.2 times to 0.95 times F.

2. The film for a semiconductor device according to claim 1, wherein G is 2 mm or more.

3. The film for a semiconductor device according to claim 1, wherein when the length from the long side of the separator to the film for the backside of a flip-chip type semiconductor is set to E, E is within the range from 1 times to 5 times F.

4. The film for a semiconductor device according to claim 1, wherein the thickness of the film for the backside of a flip-chip type semiconductor is 5 μm to 100 μm.

5. The film for a semiconductor device according to claim 1, wherein the film for a semiconductor device is wound in a roll shape.

6. A method for manufacturing a semiconductor device having steps of:
peeling the film with attached dicing tape for the backside of a flip-chip type semiconductor from the film for a semiconductor device according to claim 1,
pasting a semiconductor wafer onto the film for the backside of a flip-chip type semiconductor of the peeled film with attached dicing tape for the backside of a flip-chip type semiconductor,
performing laser marking on the film for the backside of a flip-chip type semiconductor,
dicing the semiconductor wafer to form a semiconductor element,
peeling the semiconductor element together with the film for the backside of a flip-chip type semiconductor from a pressure-sensitive adhesive layer, and
flip-chip bonding the semiconductor element to an adherend.

7. A semiconductor device manufactured with the method for manufacturing a semiconductor device according to claim 6.
